(19) United States
(12) Patent Application Publication
(10) Pub. No.: US 2025/0098493 A1
(43) Pub. Date: Mar. 20, 2025

(54) DISPLAY PANEL AND DISPLAY DEVICE

(71) Applicants: Yunnan Invensight Optoelectronics Technology Co., Ltd., Yunnan (CN); BOE Technology Group Co., Ltd., Beijing (CN)

(72) Inventor: Zongshun YANG, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/289,750

(22) PCT Filed: Feb. 1, 2023
(86) PCT No.: PCT/CN2023/074101

§ 371 Date: Nov. 7, 2023

(51) Int. Cl. H10K 59/80

(52) U.S. Cl. CPC H10K 59/879

(57) ABSTRACT

Provided is a display panel. The display panel includes: a base substrate; a plurality of sub-pixels disposed on the base substrate, wherein each of the plurality of sub-pixels includes a light-emitting region, wherein an orthographic projection of the light-emitting region on the base substrate is in an elongated-structure shape, a length of the elongated-structure in a first direction is different from a length of the elongated-structure in a second direction; and a plurality of microlens structures disposed on a side, away from the base substrate, of the plurality of sub-pixels and in one-to-one correspondence to the plurality of sub-pixels, wherein an orthographic projection of each of the plurality of microlens structures on the base substrate covers an orthographic projection of the light-emitting region of the corresponding sub-pixel on the base substrate.

### CROSS-REFERENCE TO RELATED APPLICATION

This application is a U.S. national stage of international application No. PCT/CN2023/074101, filed on Feb. 1, 2023, the disclosure of which is incorporated herein by reference in its entirety.

### TECHNICAL FIELD

The present disclosure relates to the field of display technologies, in particular to a display panel and a display device.

### BACKGROUND

Organic light-emitting diode (OLED) display panels have been widely used in the display field due to the characteristics such as self-luminescence, low energy consumption, low cost, wide viewing angle, low driving voltage, and fast response.

### SUMMARY

Embodiments of the present disclosure provide a display panel and a display device. The technical solutions are as follows.

In some embodiments of the present disclosure, a display panel is provided. The display panel includes:
a base substrate;
a plurality of sub-pixels disposed on the base substrate, wherein each of the plurality of sub-pixels includes a light-emitting region, wherein an orthographic projection of the light-emitting region on the base substrate is in an elongated-structure shape, a length of the elongated-structure in a first direction is different from a length of the elongated-structure in a second direction; and
a plurality of microlens structures disposed on a side, away from the base substrate, of the plurality of sub-pixels and in one-to-one correspondence to the plurality of sub-pixels, wherein an orthographic projection of each of the plurality of microlens structures on the base substrate covers an orthographic projection of the light-emitting region of the corresponding sub-pixel on the base substrate;
wherein a length of the orthographic projection of each of the plurality of microlens structures on the base substrate in the first direction is different from a length of the orthographic projection of the each of the plurality of microlens structures on the base substrate in the second direction, and each of the plurality of microlens structures includes a curved surface away from the base substrate, wherein a curvature of the curved surface in the first direction is different from a curvature of the curved surface in the second direction, the first direction being intersected with the second direction.

In some embodiments, the length of the elongated-structure in the first direction is greater than the length of the elongated-structure in the second direction; and

the length of the orthographic projection of each of the plurality of microlens structures on the base substrate in the first direction is greater than the length of the orthographic projection of the each of the plurality of microlens structures on the base substrate in the second direction.

In some embodiments, the curvature of the curved surface of each of the plurality of microlens structures in the first direction is less than the curvature of the curved surface of the each of the plurality of microlens structures in the second direction.

In some embodiments, a width of a gap between two adjacent microlens structures in the plurality of microlens structures is negatively correlated with the curvatures of the two adjacent microlens structures at the gap.

In some embodiments, a width of the gap between two adjacent microlens structures in the plurality of microlens structures arranged in the first direction is greater than a width of the gap between two adjacent microlens structures in the plurality of microlens structures arranged in the second direction.

In some embodiments, a curvature of a first side of the curved surface of each of the plurality of microlens structures is different from a curvature of a second side of the curved surface of the each of the plurality of microlens structures;

and the first side and the second side of the curved surface of each of the plurality of microlens structures are two sides of the each of the plurality of microlens structures in the first direction.

In some embodiments, in the first direction, the curvatures of the curved surface of each of the plurality of microlens structures at positions of different heights are different.

In some embodiments, in the first direction, the curvature of the curved surface of each of the plurality of microlens structures at a target position is negatively correlated with a distance between the target position and a face, close to the base substrate, of the each of the plurality of microlens structures.

In some embodiments, the display panel has a first region and a second region arranged in the first direction and symmetrical about an axis of the display panel in the second direction; wherein
in the first region and the second region, the curvature of the first side of the curved surface of each of the plurality of microlens structures is greater than the curvature of the second side of the curved surface of the each of the plurality of microlens structures; or
in the first region and the second region, the curvature of the first side of the curved surface of each of the plurality of microlens structures is less than the curvature of the second side of the curved surface of the each of the plurality of microlens structures; or
in the first region, the curvature of the first side of the curved surface of each of the plurality of microlens structures is less than the curvature of the second side of the curved surface of the each of the plurality of microlens structures; and in the second region, the curvature of the first side of the curved surface of each of the plurality of microlens structures is greater than the curvature of the second side of the curved surface of the each of the plurality of microlens structures.

In some embodiments, the plurality of microlens structures form a plurality of microlens groups arranged in the first direction, wherein each of the plurality of microlens groups includes a plurality of microlens structures arranged in the second direction;

wherein in a first microlens group and a second microlens group adjacent to each other in the first direction, axes of microlens structures in the first microlens group in the first direction are disposed in gaps between two adjacent microlens structures in the second microlens group.

In some embodiments, the axes of the microlens structures in the first microlens group in the first direction are overlapped with axes of the gaps between two adjacent microlens structures in the second microlens group.

In some embodiments, each of the plurality of sub-pixels includes a pixel circuit and a light-emitting unit laminated in a direction away from the base substrate; wherein
the light-emitting unit includes an anode, a light-emitting layer, and a cathode layer, wherein the anode is electrically connected to the pixel circuit,
an orthographic projection of a connection position where the anode is electrically connected to the pixel circuit on the base substrate is within an orthographic projection of the gap between adjacent microlens structures in the first direction on the base substrate.

In some embodiments, the anode includes a first portion and a second portion;
wherein an orthographic projection of the first portion on the base substrate is within the orthographic projection of the microlens structure on the base substrate, an orthographic projection of the second portion on the base substrate is within the orthographic projection of the gap between the microlens structures in the first direction on the base substrate; and the second portion is electrically connected to the pixel circuit.
In some embodiments, a center of the orthographic projection of the microlens structure on the base substrate is not overlapped with a center of the orthographic projection of the second portion on the base substrate.

In some embodiments, a center of a triangle formed by a center of a first target microlens structure in the first microlens group, and a center of a second target microlens structure and a center of a third target microlens structure in the second microlens group is within the orthographic projection of the connection position on the base substrate;

wherein the second target microlens structure and the third target microlens structure are two microlens structures closest to the first target microlens structure in the second microlens group.

In some embodiments, the display panel further includes a plurality of compensation microlens structures; wherein

each of the plurality of compensation microlens structures is disposed in the gap between any two microlens structures.

In some embodiments, the plurality of compensation microlens structures and at least one microlens structure are arranged in the first direction; or,

the plurality of compensation microlens structures and at least one microlens structure are arranged in the second direction.

In some embodiments, a gap is present between an orthographic projection of the compensation microlens structure on the base substrate and the orthographic projection of the microlens structure on the base substrate.

In some embodiments, the plurality of compensation microlens structures and the plurality of microlens structures are prepared by a one patterning process.

In some embodiments of the present disclosure, a display device is provided. The display device includes: a power supply assembly and the display panel according to the above embodiments;

wherein the power supply component is configured to supply power to the display panel.

### BRIEF DESCRIPTION OF DRAWINGS

For clearer description of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display panel according to some embodiments of the present disclosure;

FIG. 2 is a partial top view of light-emitting regions of sub-pixels and microlens structures according to some embodiments of the present disclosure;

FIG. 3 is a partial top view of light-emitting regions of sub-pixels according to some embodiments of the present disclosure;

FIG. 4 is a partial top view of microlens structures according to some embodiments of the present disclosure;

FIG. 5 is a schematic diagram of an electron microscope of an anode and a conductive material according to some embodiments of the present disclosure;

FIG. 6 is a schematic diagram of a connection position according to some embodiments of the present disclosure;

FIG. 7 is a schematic structural diagram of an anode according to some embodiments of the present disclosure;

FIG. 8 is a partial top view of light-emitting regions of sub-pixels and microlens structures according to some embodiments of the present disclosure;

FIG. 9 is a schematic structural diagram of a display panel according to some embodiments of the present disclosure;

FIG. 10 is a cross-sectional view of the microlens structure shown in FIG. 4 in an AA direction;

FIG. 11 is a cross-sectional view of the microlens structure shown in FIG. 4 in a BB direction;

FIG. 12 is a partial top view of microlens structures and compensation microlens structures according to some embodiments of the present disclosure;

FIG. 13 is a partial top view of another microlens structures and compensation microlens structures according to some embodiments of the present disclosure;

FIG. 14 is a schematic diagram of an electron microscope of microlens structures according to some embodiments of the present disclosure;

FIG. 15 is a cross-sectional view of FIG. 14 in a CC direction;

FIG. 16 is a cross-sectional view of FIG. 14 in a DD direction; and

FIG. 17 is a schematic structural diagram of a display device according to some embodiments of the present disclosure.

### DETAILED DESCRIPTION

For clearer descriptions of the objectives, technical solutions, and advantages of the present disclosure, the present disclosure will be further described in detail hereinafter with reference to the accompanying drawings.

In some practices, a microlens structure is disposed on a display side of an OLED display panel, and the microlens structure converges edge light towards a front viewing angle direction to improve brightness of the OLED display panel in the front viewing angle direction and a light utilization rate.

However, the microlens structure in some practices is usually of a hemispherical structure, such that only sub-pixels of which light-emitting regions are regularly polygonal are fitted, and the flexibility is relatively poor.

FIG. 1 is a schematic structural diagram of a display panel according to some embodiments of the present disclosure. Referring to FIG. 1, it can be seen that the display panel 10 includes a base substrate 101, a plurality of sub-pixels 102 disposed on the base substrate 101, and microlens structures 103 disposed on a side, away from the base substrate 101, of the plurality of sub-pixels 102 and in one-to-one correspondence to the plurality of sub-pixels 102. The light emitted by each sub-pixel 102 is emitted upon being converged by a corresponding microlens structure 103. For example, each microlens structure 103 is configured to converge the light emitted by the corresponding sub-pixel 102 towards the front viewing angle direction, and the front viewing angle direction is a direction perpendicular to a bearing face of the base substrate 101.

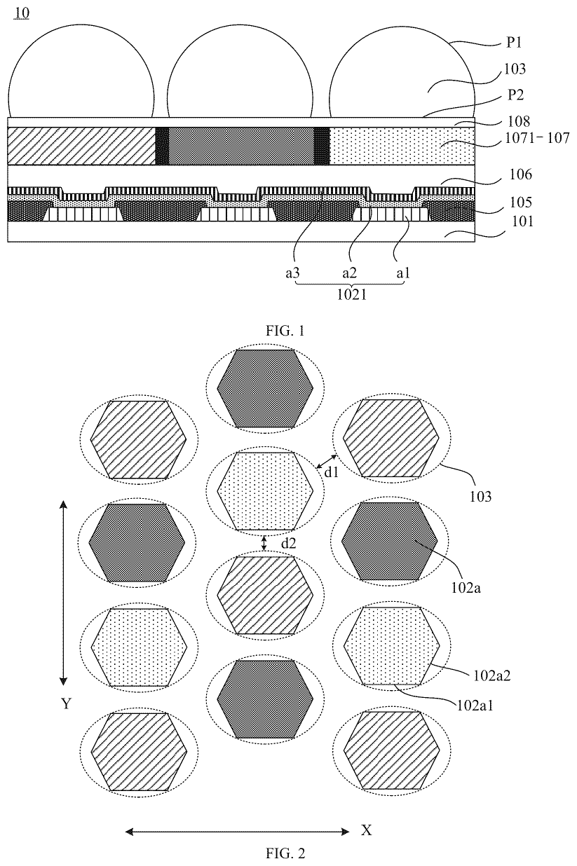

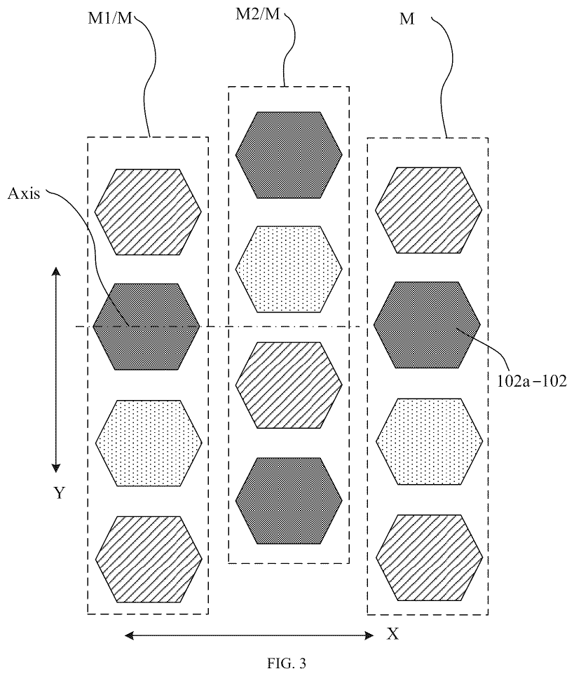

FIG. 2 is a partial top view of light-emitting regions of sub-pixels and microlens structures according to some embodiments of the present disclosure. Referring to FIG. 2, each sub-pixel 102 includes a light-emitting region 102a, an orthographic projection of the light-emitting region 102a on the base substrate 101 is in an elongated-structure shape, and a length of the elongated-structure in a first direction X is different from a length of the elongated-structure in a second direction. The elongated-structure is in a polygonal or non-polygonal shape. FIG. 2 is illustrated by taking the orthographic projection of the light-emitting region 102a on the base substrate 101 being in a hexagon shape and the length of the hexagon in the first direction X being greater than the length of the hexagon in the second direction Y as an example.

In the embodiments of the present disclosure, as the lengths of the elongated-structure formed by the orthographic projection of the light-emitting region 102a on the base substrate 101 in the first direction X and in the second direction Y are different, the lengths and curvatures of the microlens structure 103 in different directions are accordingly adjusted to enable the microlens structure 103 to be fitted with the sub-pixel 102 of which the light-emitting region 102a is in the elongated-structure shape.

The length of the orthographic projection of the microlens structure 103 on the base substrate 101 in the first direction X is different from the length of the orthographic projection of the microlens structure 103 on the base substrate 101 in the second direction Y. In addition, referring to FIG. 1, the microlens structure 103 includes a curved surface P1. The curved surface P1 is a surface of the microlens structure 103 away from the base substrate 101. The curvature of the curved surface of the microlens structure 103 in the first direction X is different from the curvature of the curved surface in the second direction Y. In addition, the microlens structure 103 also includes a plane P2, and the plane P2 is a face, close to the base substrate 101, of the microlens structure 103.

That is, the microlens structure 103 in the display panel 10 according to the embodiments of the present disclosure is not a hemispherical lens, but a lens matched with the light-emitting region 102a of the sub-pixel 102, so that the designed microlens structure 103 deflects the light in the light-emitting region 102a of the sub-pixel 102 towards the front viewing angle direction, and the brightness of the display panel 10 in the front viewing angle direction is improved.

In summary, the embodiments of the present disclosure provide a display panel. As the lengths of the elongated-structure formed by the light-emitting region of the sub-pixel in the display panel in the first direction and the second direction are different, the lengths of the microlens structure in the first direction and the second direction are different, and the curvatures of the curved surface of the microlens structure in the first direction and the second direction are different, the microlens structures are fitted with the sub-pixels of which the light-emitting regions are the elongated-structures, and the flexibility is great. Moreover, the microlens structures can deflect the light emitted by the sub-pixels towards the front viewing angle direction, such that the brightness of the display panel in the front viewing angle direction is further improved, and the display effect of the display panel is great.

In the embodiments of the present disclosure, the length of the elongated-structure in the first direction X is greater than the length of the elongated-structure in the second direction Y. Accordingly, the length of the orthographic projection of the microlens structure 103 on the base substrate 101 in the first direction X is greater than the length of the orthographic projection of the microlens structure 103 on the base substrate 101 in the second direction Y to enable the microlens structure 103 to be fitted with the light-emitting region 102a.

The first direction X is a pixel row direction of the display panel 10, and the second direction Y is a pixel column direction of the display panel 10. In some embodiments, the first direction X is the pixel column direction of the display panel 10, and the second direction Y is the pixel row direction of the display panel 10. The first direction X and the second direction Y are not specifically limited in the embodiments of the present disclosure.

In some embodiments, referring to FIG. 2, where the elongated-structure formed by the light-emitting region 102a is in a polygon shape (for example, a hexagon), the polygon at least includes a first side 102a1 and a second side 102a2, the first side 102a1 extends in the first direction X, and the second side 102a2 is adjacent to the first side 102a1 and is intersected with an extending direction of the first side 102a1, a length of the first side 102a1 is greater than a length of the second side 102a2, that is, the polygon is a non-regular polygon.

In the embodiments of the present disclosure, where the length of the orthographic projection of the microlens structure 103 on the base substrate 101 in the first target direction is greater than the length of the orthographic projection of the microlens structure 103 on the base substrate 101 in the second target direction, a slope attenuation degree of the curved surface of the microlens structure 103 in a first target direction is greater than a slope attenuation degree of the curved surface of the microlens structure 103 in a second target direction on the premise that the height of the microlens structure 103 in the direction perpendicular to the bearing surface of the base substrate 101 is fixed (the height of the microlens structure 103 in any direction is the same). The first target direction and the second target direction are two intersected directions.

Therefore, the curvature of the microlens structure 103 in a direction is negatively correlated with the length of the microlens structure 103 in the direction. That is, the greater the length of the microlens structure 103 in a direction, the less the curvature of the microlens structure 103 in the direction; the less the length of the microlens structure 103 in a direction, the greater the curvature of the microlens structure 103 in the direction.

In the embodiments of the present disclosure, the length of the orthographic projection of the microlens structure 103 on the base substrate 101 in the first direction X is greater than the length of the orthographic projection of the microlens structure 103 on the base substrate 101 in the second direction Y. Therefore, the curvature of the curved surface of the microlens structure 103 in the first direction X is less than the curvature of the curved surface of the microlens structure 103 in the second direction Y.

For the microlens structure 103, a light converging capability (that is, a light gathering capability) is positively correlated with the curvature. However, a viewing angle attenuation speed of the display panel is positively correlated with the light gathering capability. Therefore, the light gathering capability of the microlens structure 103 in the first direction X is less than the light gathering capability of the microlens structure 103 in the second direction Y, and the viewing angle attenuation speed of the display panel in the first direction X is less than the viewing angle attenuation speed of the display panel in the second direction Y. That is, the viewing effect of the display panel 10 in the first direction X is great, and the viewing effect in the second direction Y is relatively poor.

Due to a preparation process of the microlens structure 103, the prepared microlens structure 103 is prone to shrink inwards at the position with a smaller curvature, so that a width of a gap between adjacent microlens structures 103 is great at the position with smaller curvature. That is, the width of the gap between two adjacent microlens structures 103 is negatively correlated with the curvatures of the microlens structures 103 at the gap. The greater the curvatures of the microlens structures 103 at the gap, the less the width of the gap between two adjacent microlens structures 103. The less the curvatures of the microlens structures 103 at the gap, the greater the width of the gap between two adjacent microlens structures 103.

Moreover, since the curvature of the curved surface of the microlens structure 103 in the first direction X is less than the curvature of the curved surface of the microlens structure 103 in the second direction Y, the gap between two adjacent microlens structures 103 arranged in the first direction X is greater than the gap between two adjacent microlens structures 103 arranged in the second direction Y.

In the embodiments of the present disclosure, referring to FIG. 3, the plurality of sub-pixels 102 form a plurality of sub-pixel groups M (illustrated by the light-emitting regions in FIG. 3) arranged in the first direction X, and each sub-pixel group M includes a plurality of sub-pixels 102 arranged in the second direction Y. In a first sub-pixel group M1 and a second sub-pixel group M2 adjacent to each other in the first direction X, axes of the light-emitting regions 102a of the sub-pixels 102 in the first sub-pixel group M1 in the first direction X are disposed in the gaps between the light-emitting regions 102a of two adjacent sub-pixels 102 in the second sub-pixel group M2. That is, the light-emitting regions 102a of the sub-pixels 102 in the adjacent sub-pixel groups M are arranged in a staggered way in the second direction Y. Therefore, the arrangement of the sub-pixels 102 is greatly improved, and an aperture ratio of the display panel 10 is improved.

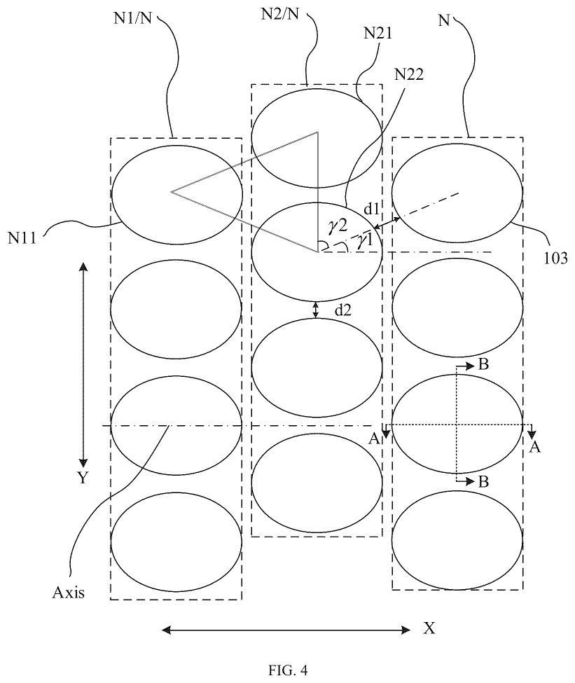

Accordingly, referring to FIG. 4, in order to enable the microlens structures 103 to be matched with the light-emitting regions 102a of the sub-pixels 102, the plurality of microlens structures 103 form a plurality of microlens groups N arranged in the first direction X, and each microlens group N includes a plurality of microlens structures 103 arranged in the second direction Y. In a first microlens group N1 and a second microlens group N2 adjacent to each other in the first direction X, axes of the microlens structures 103 in the first microlens group N1 in the first direction X are disposed in the gaps between two adjacent microlens structures 103 in the second microlens group N2. That is, the microlens structures 103 in adjacent microlens groups N are arranged in a staggered way in the second direction Y.

In some embodiments, the axes of the microlens structures 103 in the first microlens group N1 in the first direction X are overlapped with axes of the gaps between two adjacent microlens structures 103 in the second microlens group N2. Therefore, arrangement symmetry of the microlens structures 103 is improved, and a display uniformity of the display panel 10 is ensured.

It should be noted that every two connection lines of a center of a first target microlens structure N11 of the first microlens group N1, and a center of a second target microlens structure N21 and a center of a third target microlens structure N22 in the second microlens group N2 form an isosceles triangle. Moreover, a distance between the center of the first target microlens structures N11 and the center of the second target microlens structure N21 is equal to a distance between the center of the first target microlens structure N11 and the center of the third target microlens structure N22 and is greater than a distance between the second target microlens structure N21 and the third target microlens structure N22.

In the embodiments of the present disclosure, the sub-pixel 102 includes a pixel circuit (not shown in the drawing) and a light-emitting unit 1021 laminated in a direction away from the base substrate 101. The light-emitting unit 1021 includes an anode a1, a light-emitting layer a2, and a cathode layer a3, and the anode a1 is electrically connected to the pixel circuit. The region where the light-emitting layer a2 is in contact with both the anode a1 and the cathode layer a3 is the light-emitting region 102a of the sub-pixel 102.

Referring to FIG. 5, since an insulating layer between the anode a1 and the pixel circuit is thicker, a via hole is usually defined in the insulating layer, a conductive material (such as tungsten) is filled in the via hole, so that the anode a1 is electrically connected to the pixel circuit through the conductive material in the via hole. That is, the connection position where the anode a1 is electrically connected to the pixel circuit is the position of the via hole. The left drawing and the right drawing in FIG. 5 have the same structure and only differ in colors.

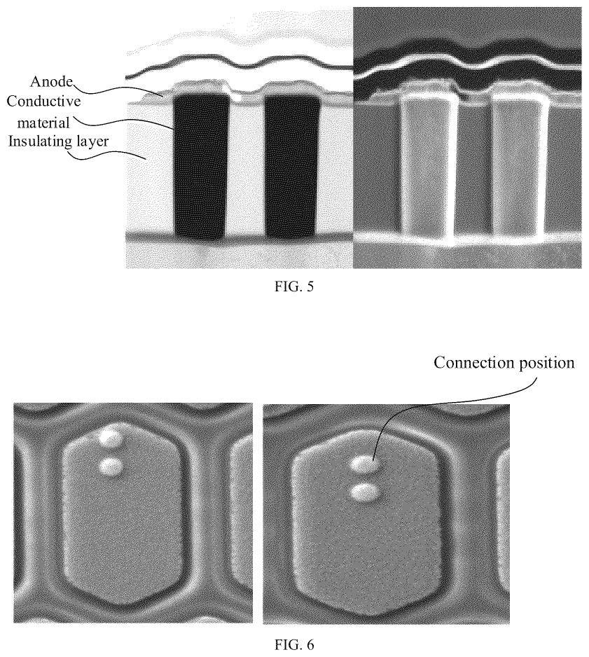

However, in general, when the conductive material is filled in the via hole, the flatness at the via hole is poorer than the flatness of other regions. Furthermore, referring to FIG. 6, where the via hole is disposed in the light-emitting region 102a of the sub-pixel 102, light-emitting uniformity of the sub-pixel 102 is possibly affected, and the display effect of the display panel 10 is relatively poor. The left drawing and the right drawing in FIG. 6 have the same structure and only differ in specific positions of the connection positions.

Therefore, an orthographic projection of the connection position where the anode a1 is electrically connected to the pixel circuit on the base substrate 101 is within the orthographic projection of the gap between adjacent microlens structures 103 on the base substrate 101 to improve the flatness of the light-emitting region 102a of the sub-pixel 102.

Moreover, since the gap between adjacent microlens structures 103 in the first direction X is greater than the gap between adjacent microlens structures 103 in the second direction Y, the orthographic projection of the connection position on the base substrate 101 is within the orthographic projection of the gap between adjacent microlens structures 103 in the first direction X on the base substrate 101.

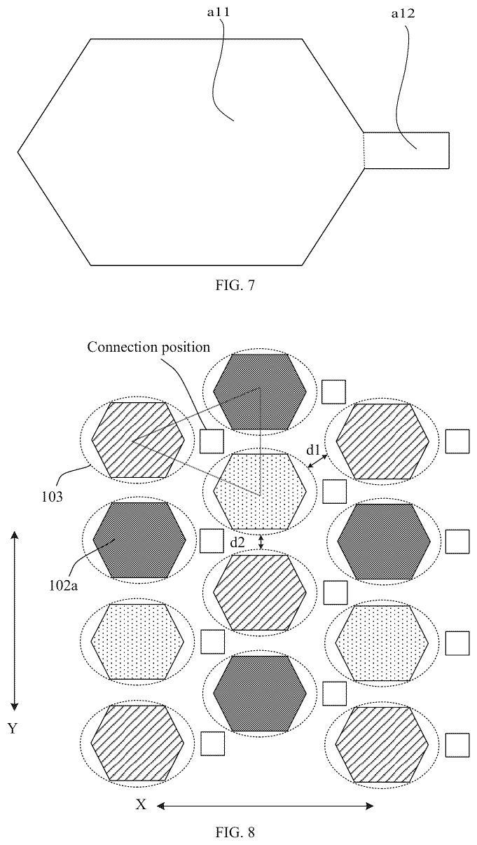

FIG. 7 is a schematic diagram of an anode and a microlens structure according to some embodiments of the present disclosure. Referring to FIG. 7, the anode a1 of the sub-pixel 102 includes a first portion a11 and a second portion a12. An orthographic projection of the first portion a11 on the base substrate 101 is within the orthographic projection of the microlens structure 103 on the base substrate 101, and an orthographic projection of the second portion a12 on the base substrate 101 is within the orthographic projection of the gap between the microlens structures 103 in the first direction X on the base substrate 101. Therefore, referring to FIG. 8, the anode a1 is electrically connected with the pixel circuit through the second portion a12, so that the electrical connection position between the anode a1 and the pixel circuit is within the orthographic projection of the gap between the microlens structures 103 in the first direction X on the base substrate 101.

In addition, in two adjacent microlens groups N, a center of a triangle formed by every two connection lines of the center of the first target microlens structure N11 in the first microlens group N1, and the center of the second target microlens structure N21 and the center of the third target microlens structure N22 in the second microlens group N2 is within the orthographic projection of the connection position on the base substrate 101. In this way, nonuniformity of the display of the sub-pixels 102 is balanced, and an optimal optical effect is achieved. The second target microlens structure N21 and the third target microlens structure N22 are two microlens structures 103 closest to the first target microlens structure N11 in the second microlens structures 103.

Referring to FIG. 4, on the premise that the microlens structures 103 in adjacent microlens groups N are arranged in a staggered way in the second direction Y, an arrangement direction of the microlens structures in the first microlens group N1 and the microlens structures 103 in the second microlens group N2 is not the first direction X. However, since the included angle γ1 between the arrangement direction of the two microlens structures 103 and the first direction X is less than the included angle γ2 between the two microlens structures 103 and the second direction Y, the width d1 of the gap between the two microlens structures 103 in the two microlens groups N is greater than the width d2 of the gap between two adjacent microlens structures 103 in the second direction Y. That is, d1>d2.

In the embodiments of the present disclosure, for the display panel 10, for customization of a viewing angle of the display panel 10, the curvature of the microlens structure 103 in the display panel 10 is adjusted, so that the curvatures of two sides of the microlens structure 103 in the same direction are designed differently.

In some embodiments, a curvature of a first side 103a of the curved surface of the microlens structure 103 is different from a curvature of a second side 103b of the curved surface of the microlens structure 103. The first side 103a and the second side 103b of the curved surface of the microlens structure 103 are two sides of the microlens structure 103 in the first direction X, thereby realizing customization of the viewing angle of the display panel 10 in the first direction X.

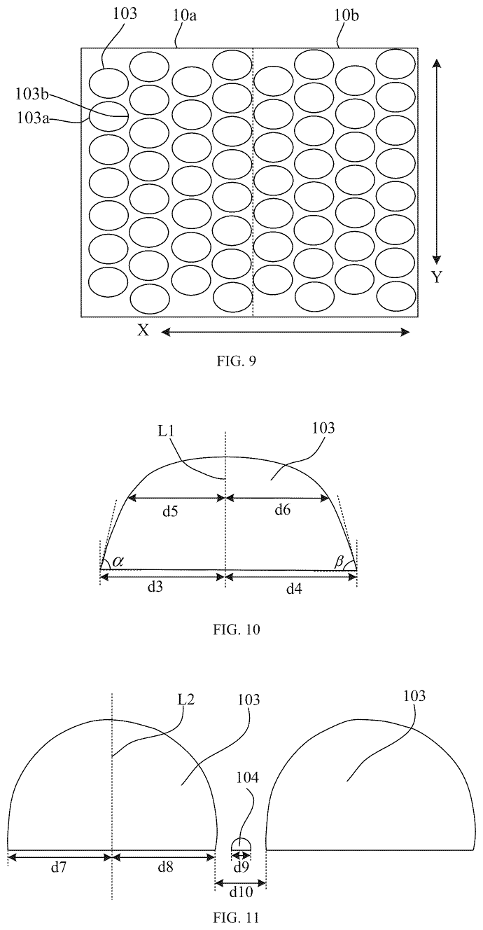

Exemplarily, referring to FIG. 9, the display panel 10 includes a first region 10a and a second region 10b arranged in the first direction X, and the first region 10a and the second region 10b are symmetrical about an axis of the display panel 10 in the second direction Y.

In a first solution, in the first region 10a and the second region 10b, the curvature of the first side 103a of the curved surface of the microlens structure 103 is greater than the curvature of the second side 103b of the curved surface of the microlens structure 103. Therefore, the light gathering capability of the first side 103a of the curved surface of the microlens structure 103 is greater the light gathering capability of the second side 103b of the curved surface of the microlens structure 103. Furthermore, the viewing angle attenuation speed of the display panel 10 on the first side 103a of the microlens structure 103 is greater than the viewing angle attenuation speed of the display panel 10 on the second side 103b of the microlens structure 103. Therefore, the customization of the viewing angle of the display panel 10 on the second side 103b of the microlens structure 103 is realized, so that the viewing effect of viewing the display panel 10 on the second side 103b of the microlens structure 103 is great. Moreover, since the light gathering capability of the first side 103a of the microlens structure 103 is great, the brightness of the light emitted from the front viewing angle of the display panel 10 is improved, and the display effect is improved.

In a second solution, in the first region 10a and the second region 10b, the curvature of the first side 103a of the curved surface of the microlens structure 103 is less than the curvature of the second side 103b of the curved surface of the microlens structure 103. Therefore, the light gathering capability of the first side 103a of the curved surface of the microlens structure 103 is less than the light gathering capability of the second side 103b of the curved surface of the microlens structure 103. Furthermore, the viewing angle attenuation speed of the display panel 10 on the first side 103a of the microlens structure 103 is less than the viewing angle attenuation speed of the display panel 10 on the second side 103b of the microlens structure 103. Therefore, the customization of the viewing angle of the display panel on the first side 103a of the microlens structure 103 is realized, so that the viewing effect of viewing the display panel 10 on the first side 103a of the microlens structure 103 is great. In addition, since the light gathering capability of the second side 103b of the microlens structure 103 is great, the brightness of the light emitted from the front viewing angle of the display panel 10 is improved, and the display effect is improved.

In a third solution, in the first region 10a, the curvature of the first side 103a of the curved surface of the microlens structure 103 is less than the curvature of the second side 103b of the curved surface of the microlens structure 103. In the second region 10b, the curvature of the first side 103a of the curved surface of the microlens structure 103 is greater than the curvature of the second side 103b of the curved surface of the microlens structure 103.

Therefore, in the first region 10a, the light gathering capability of the first side 103a of the curved surface of the microlens structure 103 is less than the light gathering capability of the second side 103b of the curved surface of the microlens structure 103. In the second region 10b, the light gathering capability of the first side 103a of the curved surface of the microlens structure 103 is enabled to be greater than the light gathering capability of the second side 103b of the curved surface of the microlens structure 103.

For the great viewing effect of viewing the display panel 10 on any one side of the microlens structure 103 (the viewing angle attenuation speed is smaller), the curvature of one side of the microlens structure 103 close to a boundary of the display panel 10 is less than the curvature of the other side of the microlens structure 103. Therefore, the first side 103a of the curved surface of the microlens structure 103 is closer to the first region 10a than the second side 103b of the curved surface of the microlens structure 103.

By combining the above three solutions, it can be seen that the designs of the curvatures of the plurality of microlens structures 103 in the display panel 10 in the first solution and the second solution are the same, and the design of the curvatures of the microlens structures 103 in the first region 10a of the display panel 10 and the design of the curvatures of the microlens structures 103 in the second region 10b of the display panel 10 are opposite in the third solution.

By taking the first solution as an example, the curvature of the first side 103a of the curved surface of the microlens structure 103 is greater than the curvature of the second side 103a of the curved surface of the microlens structure 103, that is, the included angle α between the first side 103a of the curved surface of the microlens structure 103 and the face, close to the base substrate 101, of the microlens structure 103 is greater than the included angle β between the second side 103b of the curved surface of the microlens structure 103 and the face, close to the base substrate 101, of the microlens structure 103. That is, α>β. Therefore, referring to FIG. 10, on a side, close to the base substrate 101, of the microlens structure 103 (the bottom of the microlens structure 103), the distance d3 between a first target dividing line L1 of the microlens structure 103 and the first side 103a of the microlens structure 103 is less than the distance d4 between the first target boundary L1 of the microlens structure 103 and the second side 103a of the microlens structure 103. That is, d3<d4. The first target dividing line L1 is a dividing line extending in the second direction Y at the position corresponding to the maximum distance between the curved surface of the microlens structure 103 and the face close to the base substrate 101. In some embodiments, d3<d4<1.1*d3.

In some embodiments, in the first direction X, the curvatures of the curved surface of the microlens structure 103 at positions of different heights are different. For example, in the first direction X, a curvature of the curved surface of the microlens structure 103 at a target position is negatively correlated with the distance between the target position and the face, close to the base substrate 101, of the microlens structure 103. That is, the greater the distance between the target position and the face, close to the base substrate 101, of the microlens structure 103, the less the curvature at the target position; the less the distance between the target position and the face, close to the base substrate 101, of the microlens structure 103, the greater the curvature at the target position.

Therefore, the curvature of the curved surface of the microlens structure 103 close to the bottom is greater than the curvature of the curved surface of the microlens structure 103 close to the top. Accordingly, the ratio of the distances between the second side 103b and the first side 103a of the microlens structure 103 and the first target dividing line L1 at a first target position of the microlens structure 103 is greater than the ratio of the distances between the second side 103b and the first side 103a of the microlens structure 103 and the first target dividing line L1 at a second target position of the microlens structure 103. The distance between the first target position of the microlens structure 103 and the side, close to the base substrate 101, of the microlens structure 103 is less than the distance between the second target position of the microlens structure 103 and the side, close to the base substrate 101, of the microlens structure 103.

In some embodiments, referring to FIG. 10, d4/d3>d6/d5. Furthermore, 1.1>d4/d3>d6/d5>1. In addition, in general, the ratio d1/d2 of the width d1 of the gap to the width d2 of the gap is greater than 1.1. Therefore, d1/d2>d4/d3. Moreover, 0.01<d1/d2−d4/d3<0.1.

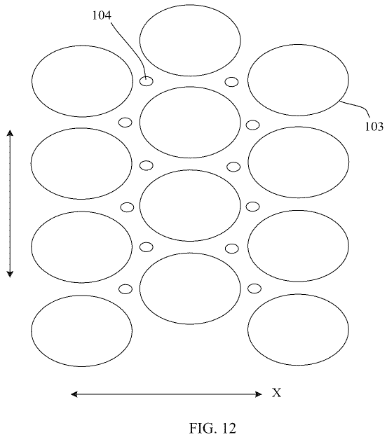

In addition, in the second direction Y, referring to FIG. 11, the curvatures of two sides of the microlens structure 103 are approximately the same, so that the ratio (d8/d7) of the distances between two sides of the microlens structure 103 and a second target dividing line L2 in the second direction Y is approximately 1. That is, d4/d3>d8/d7.

In the embodiments of the present disclosure, since the curvatures of two sides of the microlens structure 103 in the first direction X are different, the center of the microlens structure 103 is offset. Thus, the center of the orthographic projection of the microlens structure 103 on the base substrate 101 is not overlapped with the center of the orthographic projection of the second portion a12 of the anode a1 on the base substrate 101.

In the embodiments of the present disclosure, the light-emitting regions 102a of the sub-pixels 102 of the display panel 10 emits light, and stray light is possibly emitted from other regions of the display panel 10. Therefore, a compensation microlens structure 104 is disposed in the gap between any two microlens structures 103 to effectively utilize the stray light and increase the brightness of the product in the front viewing angle direction. In some embodiments, the display panel 10 includes a plurality of compensation microlens structures 104, and each compensation microlens structure 104 is disposed in the gap between any two microlens structures 103.

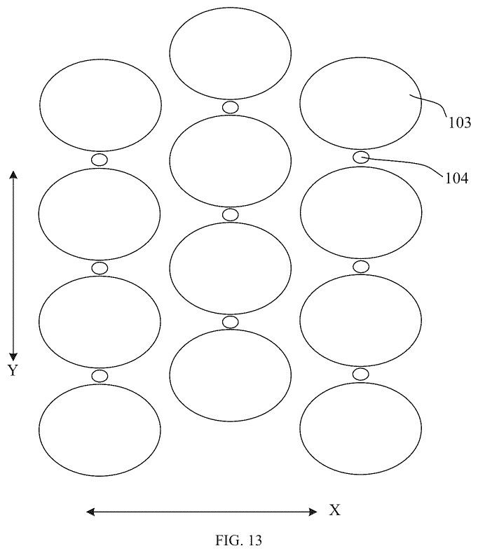

Exemplarily, referring to FIG. 12, the compensation microlens structures 104 and at least one microlens structure 103 are arranged in the first direction X. Alternatively, referring to FIG. 13, the compensation microlens structures 104 and at least one microlens structure 103 are arranged in the second direction Y.

It should be noted that a gap is present between an orthographic projection of the compensation microlens structure 104 on the base substrate 101 and the orthographic projection of the microlens structure 103 on the base substrate 101 to avoid the influence on light convergence caused by mutual adhesion of the compensation microlens structure 104 and the microlens structure 103. That is, d9<d10.

In the embodiments of the present disclosure, the compensation microlens structure 104 and the microlens structure 103 are prepared by a one patterning process. That is, materials of the compensation microlens structure 104 and the microlens structure 103 are the same.

In some embodiments, the process of preparing the compensation microlens structures 104 and the microlens structures 103 includes: coating lens glue on a side, away from the base substrate 101, of the plurality of sub-pixels 102, exposing the lens glue by a halftone mask, developing the exposed lens glue, and acquiring the microlens structures 103 and the compensation microlens structures 104 by high temperature baking and hot melt molding.

The halftone mask is completely blocked in the region where the microlens structures 103 are disposed, and is semi-light-transmitted in the region where the compensation microlens structures 104 are disposed. In the region where the compensation microlens structures 104 are disposed, the lens glue on the upper half is removed by exposing and developing, and a thinner portion is remained to form the compensation microlens structures 104 by heat melting.

In addition, a temperature of the high temperature baking and hot melt molding ranges from 100° C. to 110° C., and the duration ranges from 30 min (minutes) to 40 min. Furthermore, the curvatures of the first sides 103a and the second sides 103b of the microlens structures 103 in the first direction X are differentially controlled based on an irradiation angle and energy of an ultraviolet (UV) irradiation lamp used in baking. An energy is controlled in a range of 2200 mj to 3500 mj. The greater the energy, the less the curvature; and the less the energy, the greater the curvature.

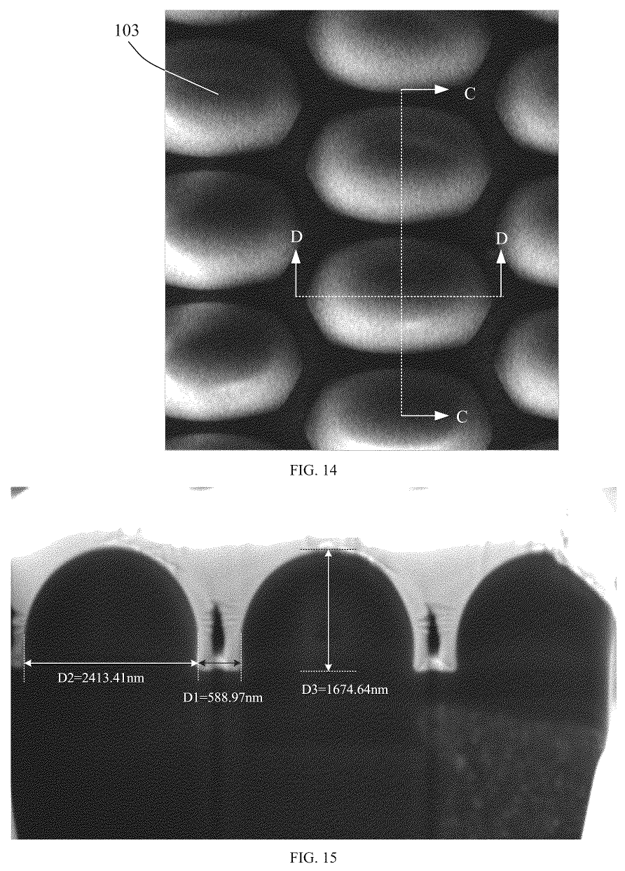

It should be noted that the microlens structures 103 or the compensation microlens structures 104 in the above FIG. 1 to FIG. 4 and FIG. 8 to FIG. 13 are an approximate shape of the product, and do not represent the shape of the actual product. Referring to FIG. 14, the orthographic projection of the microlens structure 103 on the base substrate 101 is approximately in an elliptical shape, and thus is configured to be fitted with the sub-pixel 102 of which the light-emitting region 102a is in a non-regular polygon shape.

In some embodiments, FIG. 15 is a cross-sectional view of FIG. 14 in a CC direction. Referring to FIG. 15, in the second direction Y, the width D1 of the gap between two adjacent microlens structures 103 is equal to 588.97 nm (nanometers), the width D2 of the microlens structure 103 in the second direction Y is equal to 2413.14 nm, and the height D3 of the microlens structure 103 is equal to 1674.64 nm.

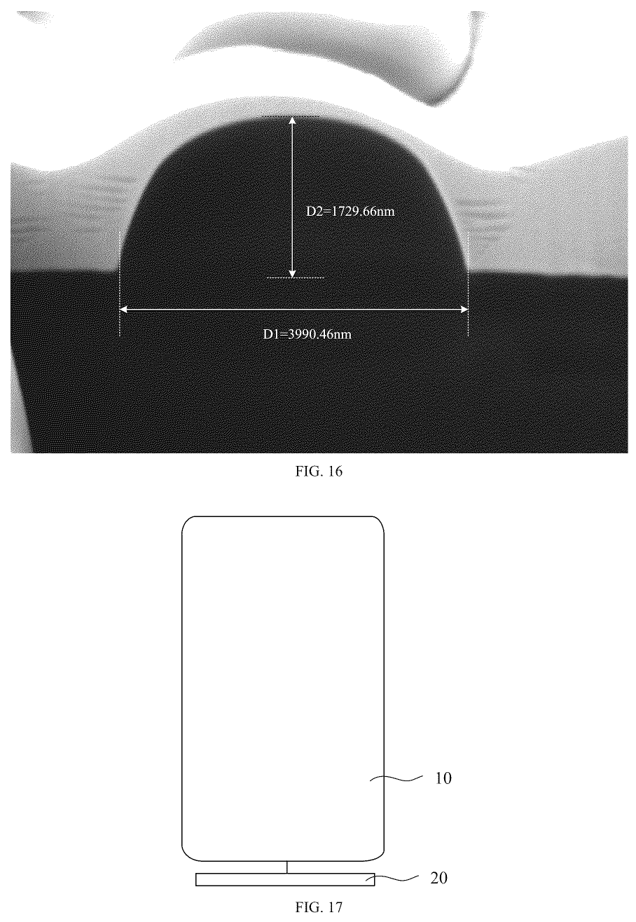

FIG. 16 is a cross-sectional view of FIG. 14 in a DD direction. Referring to FIG. 16, the width D1 of the microlens structure 103 in the first direction X is equal to 3990.46 nm, and the height D2 of the microlens structure 103 is equal to 1729.66 nm.

Thus, it can be seen that the height of the microlens structure 103 in the first direction X and the height of the microlens structure 103 in the second direction Y are different, but the difference is not significant.

It should be noted that the various sizes in FIG. 15 and FIG. 16 are only schematic, and actual sizes are designed based on the sub-pixels in the actual product.

In the embodiments of the present disclosure, referring to FIG. 1, the display panel 10 further includes a pixel definition layer 105, a packaging layer 106, a color film layer 107, and a planarization layer 108.

The pixel definition layer 105 is disposed on a side, away from the base substrate 101, of the anodes a1 and includes a plurality of hollowed-out regions, and each hollowed-out region is configured to expose one anode a1, so that the anodes a1 are in contact with the light-emitting layers a2.

The packaging layer 106 is disposed on a side, away from the base substrate 101, of the cathode layer a3, and is configured to package the sub-pixels 102 in the display panel 10 to prevent the sub-pixels 102 from being corroded by moisture and oxygen.

The color film layer 107 is disposed on a side, away from the base substrate 1014, of the packaging layer 106 and includes a plurality of color resistance blocks of different colors. The light-emitting region of each sub-pixel 102 is within an orthographic projection of the color resistance block on the base substrate 101.

Exemplarily, FIG. 1 shows three sub-pixels and three color resistance blocks 1071. From left to right, the color of the first color resistance block 1071 is red, the color of the second color resistance block 1071 is green, and the color of the third color resistance block 1071 is blue.

Since the light emitted by the sub-pixels 102 in the display panel 10 according to the embodiments of the present disclosure is white light, by disposing the color film layer 107 on the side, away from the base substrate 101, of the sub-pixels 102, the light of multiple different colors is emitted after the white light passes through the color resistance blocks 1071 of different colors in the color film layer 107, and a color gamut of the display panel 10 is great.

In summary, the embodiments of the present disclosure provide a display panel. As the lengths of the elongated-structure formed by the light-emitting region of the sub-pixel in the display panel in the first direction and the second direction are different, the lengths of the microlens structure in the first direction and the second direction are different, and the curvatures of the curved surface of the microlens structure in the first direction and the second direction are different, the microlens structures are fitted with the sub-pixels of which the light-emitting regions are the elongated-structures, and the flexibility is great. Moreover, the microlens structures can deflect the light emitted by the sub-pixels towards the front viewing angle direction, such that the brightness of the display panel in the front viewing angle direction is further improved, and the display effect of the display panel is great.

FIG. 17 is a schematic structural diagram of a display device according to some embodiments of the present disclosure. Referring to FIG. 17, the display device includes a power supply assembly 20 and the display panel 10 according to the above embodiments. The power supply assembly 20 is configured to supply power to the display panel 10.

In the embodiments of the present disclosure, the display device is an active-matrix organic light-emitting diode (AMOLED) display device, a passive-matrix organic light-emitting diode (PMOLED) display device, a quantum dot light-emitting diode (QLED) display device, electronic paper, a mobile phone, a tablet computer, a television, a monitor, a notebook computer, a digital photo frame or a navigator and any other products or components with a display function.

Since the display device can achieve the basically same technical effects as the display panel described in the above embodiments, the technical effects of the display device are not repeated herein for the sake of brevity.

It should be understood that although the terms “first,” “second,” and the like can be used herein to describe various elements, components, regions, layers, and/or parts, these elements, components, regions, layers, and/or parts should not be limited by these terms. These terms are only configured to distinguish one element, component, region, layer, or part from another region, layer, or part. Accordingly, the first element, component, region, layer, or part discussed above may be referred to as a second element, component, region, layer, or part without departing from teachings of the present disclosure.

Spatial relative terms such as “below,” “above,” “left,” “right,” and the like can be configured to describe the relationship between one element or feature and another element(s) or feature(s) as shown in the figures for convenience of descriptions. It should be understood that these spatial relative terms are intended to cover different orientations of devices in use or operation other than those depicted in the drawings. For example, where the device in the drawing is turned over, the element described as “below other elements or features” will be oriented as “above other elements or features.” Therefore, the exemplary term “below” can cover both orientations of above and below. The device may be oriented in other ways (rotated by 90 degrees or in other orientations), and spatial relative descriptors used herein should be interpreted accordingly. In addition, it should also be understood that when a layer is referred to as “between two layers”, it may be the only layer between the two layers, or there may be one or more intermediate layers.

The terms used herein are only for the purpose of describing specific embodiments and not intended to limit the present disclosure. As used herein, the singular forms “one,” “a,” and “the” are intended to include plural forms, unless the context clearly indicates otherwise. It should be further understood that the terms “including” and/or “containing” specify the presence of said features, integers, steps, operations, elements, and/or components when used in the description, without excluding the presence or addition of one or more other features, integers, steps, operations, elements, components, and/or groups thereof. As used herein, the term “and/or” includes any and all combinations of one or more of the associated listed items. In the description, specific features, structures, materials or characteristics may be combined in any one or more embodiments or examples in a suitable way. In addition, those skilled in the art can combine different embodiments or examples and features of different embodiments or examples described in the description without contradicting each other.

Unless otherwise defined, all terms (including technical terms and scientific terms) used herein have the same meanings as commonly understood by those ordinary skilled in the art to which the present disclosure belongs. It should be further understood that the terms such as those defined in commonly used dictionaries should be interpreted as having meanings consistent with their meanings in relevant arts and/or in the context of the description, and will not be interpreted in an idealized or overly formal sense unless explicitly defined herein.

Described above are merely optional embodiments of the present disclosure, and are not intended to limit the present disclosure. Any modifications, equivalent substitutions, improvements, and the like within the spirit and principles of the disclosure shall fall within the protection scope of the present disclosure.

1. A display panel, comprising:
a base substrate;
a plurality of sub-pixels disposed on the base substrate, wherein each of the plurality of sub-pixels comprises a light-emitting region, wherein an orthographic projection of the light-emitting region on the base substrate is in an elongated-structure shape, a length of the elongated-structure in a first direction is different from a length of the elongated-structure in a second direction; and
a plurality of microlens structures disposed on a side, away from the base substrate, of the plurality of sub-pixels and in one-to-one correspondence to the plurality of sub-pixels, wherein an orthographic projection of each of the plurality of microlens structures on the base substrate covers an orthographic projection of the light-emitting region of the corresponding sub-pixel on the base substrate;
wherein a length of the orthographic projection of each of the plurality of microlens structures on the base substrate in the first direction is different from a length of the orthographic projection of the each of the plurality of microlens structures on the base substrate in the second direction, and each of the plurality of microlens structures comprises a curved surface away from the base substrate, wherein a curvature of the curved surface in the first direction is different from a curvature of the curved surface in the second direction, the first direction being intersected with the second direction.

2. The display panel according to claim 1, wherein
the length of the elongated-structure in the first direction is greater than the length of the elongated-structure in the second direction; and
the length of the orthographic projection of each of the plurality of microlens structures on the base substrate in the first direction is greater than the length of the orthographic projection of the each of the plurality of microlens structures on the base substrate in the second direction.

3. The display panel according to claim 2, wherein the curvature of the curved surface of each of the plurality of microlens structures in the first direction is less than the curvature of the curved surface of the each of the plurality of microlens structures in the second direction.

4. The display panel according to claim 3, wherein a width of a gap between two adjacent microlens structures in the plurality of microlens structures is negatively correlated with the curvatures of the two adjacent microlens structures at the gap.

5. The display panel according to claim 4, wherein a width of the gap between two adjacent microlens structures in the plurality of microlens structures arranged in the first direction is greater than a width of the gap between two adjacent microlens structures in the plurality of microlens structures arranged in the second direction.

6. The display panel according to claim 1, wherein a curvature of a first side of the curved surface of each of the plurality of microlens structures is different from a curvature of a second side of the curved surface of the each of the plurality of microlens structures, and the first side and the second side of the curved surface of each of the plurality of microlens structures are two sides of the each of the plurality of microlens structures in the first direction.

7. The display panel according to claim 6, wherein in the first direction, the curvatures of the curved surface of each of the plurality of microlens structures at positions of different heights are different.

8. The display panel according to claim 7, wherein in the first direction, the curvature of the curved surface of each of the plurality of microlens structures at a target position is negatively correlated with a distance between the target position and a face, close to the base substrate, of the each of the plurality of microlens structures.

9. The display panel according to claim 6, further comprising: a first region and a second region arranged in the first direction and symmetrical about an axis of the display panel in the second direction; wherein
in the first region and the second region, the curvature of the first side of the curved surface of each of the plurality of microlens structures is greater than the curvature of the second side of the curved surface of the each of the plurality of microlens structures; or
in the first region and the second region, the curvature of the first side of the curved surface of each of the plurality of microlens structures is less than the curvature of the second side of the curved surface of the each of the plurality of microlens structures; or
in the first region, the curvature of the first side of the curved surface of each of the plurality of microlens structures is less than the curvature of the second side of the curved surface of the each of the plurality of microlens structures; and in the second region, the curvature of the first side of the curved surface of each of the plurality of microlens structures is greater than the curvature of the second side of the curved surface of the each of the plurality of microlens structures.

10. The display panel according to claim 1, wherein the plurality of microlens structures form a plurality of microlens groups arranged in the first direction, wherein each of the plurality of microlens groups comprises a plurality of microlens structures arranged in the second direction;
wherein in a first microlens group and a second microlens group adjacent to each other in the first direction, axes of microlens structures in the first microlens group in the first direction are disposed in gaps between two adjacent microlens structures in the second microlens group.

11. The display panel according to claim 10, wherein the axes of the microlens structures in the first microlens group in the first direction are overlapped with axes of the gaps between two adjacent microlens structures in the second microlens group.

12. The display panel according to claim 10, wherein each of the plurality of sub-pixels comprises a pixel circuit and a light-emitting unit laminated in a direction away from the base substrate; wherein the light-emitting unit comprises an anode, a light-emitting layer, and a cathode layer, wherein the anode is electrically connected to the pixel circuit, an orthographic projection of a connection position where the anode is electrically connected to the pixel circuit on the base substrate is within an orthographic projection of the gap between adjacent microlens structures in the first direction on the base substrate.

13. The display panel according to claim 12, wherein the anode comprises a first portion and a second portion; wherein an orthographic projection of the first portion on the base substrate is within the orthographic projection of the microlens structure on the base substrate, an orthographic projection of the second portion on the base substrate is within the orthographic projection of the gap between the microlens structures in the first direction on the base substrate, and the second portion is electrically connected to the pixel circuit.

14. The display panel according to claim 13, wherein a center of the orthographic projection of the microlens structure on the base substrate is not overlapped with a center of the orthographic projection of the second portion on the base substrate.

15. The display panel according to claim 12, wherein a center of a triangle formed by a center of a first target microlens structure in the first microlens group, and a center of a second target microlens structure and a center of a third target microlens structure in the second microlens group is within the orthographic projection of the connection position on the base substrate; wherein the second target microlens structure and the third target microlens structure are two microlens structures closest to the first target microlens structure in the second microlens group.

16. The display panel according to claim 1, further comprising: a plurality of compensation microlens structures; wherein each of the plurality of compensation microlens structures is disposed in the gap between any two microlens structures.

17. The display panel according to claim 16, wherein
the plurality of compensation microlens structures and at least one microlens structure are arranged in the first direction; or
the plurality of compensation microlens structures and at least one microlens structure are arranged in the second direction.

18. The display panel according to claim 16, wherein a gap is present between an orthographic projection of the compensation microlens structure on the base substrate and the orthographic projection of the microlens structure on the base substrate.

19. The display panel according to claim 16, wherein the plurality of compensation microlens structures and the plurality of microlens structures are prepared by a one patterning process.

20. A display device, comprising: a power supply assembly and a display panel; wherein
the display panel comprises:
a base substrate;
a plurality of sub-pixels disposed on the base substrate, wherein each of the plurality of sub-pixels comprises a light-emitting region, wherein an orthographic projection of the light-emitting region on the base substrate is in an elongated-structure shape, a length of the elongated-structure in a first direction is different from a length of the elongated-structure in a second direction; and
a plurality of microlens structures disposed on a side, away from the base substrate, of the plurality of sub-pixels and in one-to-one correspondence to the plurality of sub-pixels, wherein an orthographic projection of each of the plurality of microlens structures on the base substrate covers an orthographic projection of the light-emitting region of the corresponding sub-pixel on the base substrate; wherein a length of the orthographic projection of each of the plurality of microlens structures on the base substrate in the first direction is different from a length of the orthographic projection of the each of the plurality of microlens structures on the base substrate in the second direction, and each of the plurality of microlens structures comprises a curved surface away from the base substrate, wherein a curvature of the curved surface in the first direction is different from a curvature of the curved surface in the second direction, the first direction being intersected with the second direction; and
the power supply component is configured to supply power to the display panel.
